(19) United States
(12) Patent Application Publication
(10) Pub. No.: US 2014/0050005 A1
(43) Pub. Date: Feb. 20, 2014

(54) NONVOLATILE MEMORY APPARATUS AND METHOD OF OPERATING THE SAME

(71) Applicant: SAMSUNG ELECTRONICS CO., LTD., Suwon-si (KR)

(72) Inventors: Hyun-sik CHOI, Hwaseong-si (KR); Ho-jung KIM, Suwon-si (KR); U-in CHUNG, Seoul (KR)

(73) Assignee: SAMSUNG ELECTRONICS CO., LTD., Suwon-Si (KR)

(21) Appl. No.: 13/747,777

(22) Filed: Jan. 23, 2013

(30) Foreign Application Priority Data
Aug. 16, 2012 (KR) 10-2012-0089669

(51) Int. Cl. G11C 7/00; G11C 17/00; G11C 11/16; G11C 13/00

(52) U.S. Cl. CPC G11C 7/00; G11C 13/0002; G11C 17/00; G11C 11/16; G11C 13/0004
USPC 365/94; 365/189.15; 365/148; 365/158; 365/163

(57) ABSTRACT

Nonvolatile memory apparatuses and methods of operating the same. A nonvolatile memory apparatus includes a nonvolatile memory cell array including a plurality of memory cells; an address decoder configured to receive computation data that indicates a computation from among a plurality of computations and an input data for computation, and the address decoder configured to output an address of the nonvolatile memory cell array corresponding to the indicated computation and input data, the nonvolatile memory cell array being configured to output result data stored at the output address, the result data corresponding to a previous computation performed before receipt of the computation data; and a reading unit configured to read the result data output from the nonvolatile memory cell array.

### CROSS-REFERENCE TO RELATED APPLICATIONS

This application claims priority under 35 U.S.C. §119 of Korean Patent Application No. 10-2012-0089669, filed on Aug. 16, 2012, in the Korean Intellectual Property Office, the disclosure of which is incorporated herein in its entirety by reference.

### BACKGROUND

1. Field

The present disclosure relates to nonvolatile memory apparatuses and methods of operating the same.

2. Description of the Related Art

Up to now, as volatile memories, DRAMs, in particular, DDR-II form a general trend, and as preservative nonvolatile memories, flash memories form a general trend. Since these two products respectively have strong points and drawbacks, both of these products have been developed in their respective fields. That is, DRAMs represented by DDR-II have strong points in realizing high speed and large capacity with a low cost. However, since they are volatile, when power is turned off, data are erased and data must be recorded continuously while power is on, and thus, power consumption is high. However, conventional nonvolatile memory devices such as an electrically erasable PROMs (EEPROMs) or flash memories have drawbacks of low operation speed, limited lifetime (approximately 100,000 times repetition of reading and writing), and operating voltage of as high as 12V. Therefore, the nonvolatile memory devices are difficult to be used in a computer main memory or a portable information communication device.

Semiconductor memory devices to be used for storing information may be divided into volatile memory apparatuses and nonvolatile memory apparatuses. In conventional computer systems, a DRAM that generally processes at a high speed is used as a main memory, and a nonvolatile memory such as a hard disc drive or a flash memory is used as an auxiliary memory device. However, as a new memory field has been developed, the replacement of the DRAM with a nonvolatile memory as the main memory has been attempted.

### SUMMARY

Provided are nonvolatile memory apparatuses that rapidly perform complicated computation by using a nonvolatile memory cell array. However, example embodiments are not limited thereto, and additional aspects will be set forth in part in the description which follows and, in part, will be apparent from the description, or may be learned by practice of the presented embodiments.

According to at least one example embodiment, there is provided a nonvolatile memory cell array including a plurality of memory cells; an address decoder configured to receive computation data that indicates a computation from among a plurality of computations and an input data for computation, and the address decoder configured to output an address of the nonvolatile memory cell array corresponding to the indicated computation and input data, the nonvolatile memory cell array being configured to output result data stored at the output address, the result data corresponding to a previous computation performed before receipt of the computation data; and a reading unit configured to read the result data output from the nonvolatile memory cell array.

The nonvolatile memory apparatus according to at least one example embodiment may increase computation speed by using result data of computation stored in a nonvolatile memory cell array in advance.

Also, when the nonvolatile memory apparatus stores the result data in the nonvolatile memory cell array, the nonvolatile memory apparatus may store coded result data or may store the result data in an OTP area of the nonvolatile memory cell array, and thus, data coding is possible.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 is a block diagram for explaining a nonvolatile memory apparatus according to at least one example embodiment;

FIG. 2 is a drawing for explaining a nonvolatile memory apparatus according to at least one example embodiment;

FIG. 3 is a drawing for explaining a nonvolatile memory apparatus that includes a plurality of sense amplifiers according to at least one example embodiment;

FIG. 4 is a drawing for explaining a nonvolatile memory apparatus that includes an OTP area according to at least one example embodiment;

FIG. 5 is a drawing for explaining a nonvolatile memory apparatus that performs a coding operation according to at least one example embodiment; and

FIG. 6 is a flowchart for explaining a method of operating a nonvolatile memory apparatus according to at least one example embodiment.

### DETAILED DESCRIPTION

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

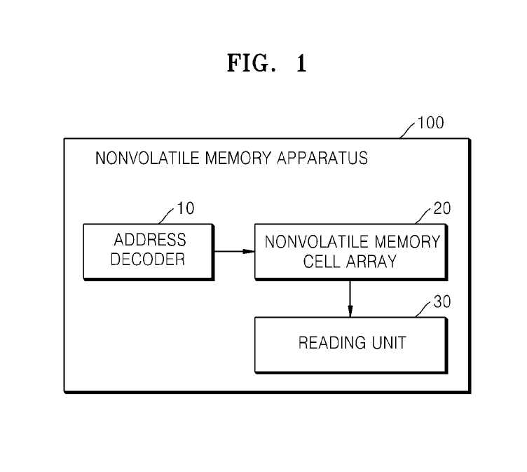

FIG. 1 is a block diagram for explaining a nonvolatile memory apparatus 100 according to at least one example embodiment. Referring to FIG. 1, the nonvolatile memory apparatus 100 includes an address decoder 10, a nonvolatile memory cell array 20, and a reading unit 30.

The address decoder 10 receives a computation data that indicates one computation among at least one computation and an input data for computation, and outputs an address of a nonvolatile memory cell array corresponding to the computation data and the input data. The computation data is a data for distinguishing which computation of the at least one computation shall be performed. In other words, the computation data is a data for determining which computation of the input data shall be performed. The address decoder 10 outputs an address corresponding to the inputted computation data and the input data. At this point, the output address stores a ‘result data’ that corresponds to the computation data and the input data, and indicates a portion of the nonvolatile memory cell array 20. For example, the output address may be a specific line address of the nonvolatile memory cell array 20.

The address decoder 10 may select a cell of the nonvolatile memory cell array 20 in response to an inputted bit data. The address decoder 10 may include a row decoder (not shown), and at this point, the address decoder 10 may select only a specific word line in response to the inputted bit data. According to at least one example embodiment, the only decoder included in the address decoder may be a row decoder.

Also, according to at least one example embodiment, the address decoder 10 may include a row decoder and a column decoder. The row decoder selects a word line in response to a row address, and the column decoder selects a bit line in response to a column address.

The row decoder and the column decoder respectively include a plurality of switches. The row decoder selects a word line by being switched in response to a row address, and the column decoder selects a bit line by being switched in response to a column address.

The nonvolatile memory cell array 20 stores the result data of computations in advance and outputs the result data stored in an address which is selected by the address decoder 10. For example, the memory cell array 20 may store result data corresponding to a result one or more previously performed computations in advance of the receipt of computation data indicating later computations, or computations intended to be performed at the time of the receipt of the computation data or later. Since the nonvolatile memory cell array 20 includes nonvolatile memory cells, even if power is turned off, the result data are not erased. According to at least one example embodiment, the nonvolatile memory cell array may include only nonvolatile cells. Accordingly, when power is supplied to the nonvolatile memory apparatus 100, the data stored in the nonvolatile memory cell array 20 may be repeatedly used.

The nonvolatile memory cell array 20 may simultaneously output result data of a line that is selected by the row decoder. When the address decoder 10 includes only a row decoder, the address decoder 10 selects a specific line of the nonvolatile memory cell array 20, and the nonvolatile memory cell array 20 simultaneously outputs the result data included in the selected line to the reading unit 30.

The nonvolatile memory cell array 20 stores result data of computations in advance. Accordingly, when a computation is needed, the nonvolatile memory cell array 20 does not perform a computation according to the input data but outputs the computation result data stored in the nonvolatile memory cell array 20. Therefore, the same result as a computation may be obtained without performing a computation. Accordingly, the result data is output faster than the case when the result data is output by performing a computation according to an input data.

For example, discrete cosine transform (DCT) or direct digital frequency synthesizer (DDFS) is realized by using a read only memory (ROM). That is, the DCT or DDFS performs computation with respect to an input data and outputs a result data that shows a result of computation by performing the required computation using a ROM. However, when a DCT or DDFS is realized, results of required computations are stored in the nonvolatile memory cell array 20 in a look-up-table type. Therefore, the same result as a computation may be obtained without performing a computation with respect to the input data.

Besides the DCT or DDFS, when a complicated and time consuming computation is required, for example, to realize a three dimensional hologram, a required time for performing a computation may be reduced by storing result data of computations in the nonvolatile memory cell array 20. Since result data stored in the nonvolatile memory cell array 20 are not erased even if power is turned off, although the power of the nonvolatile memory apparatus 100 is turned off and restarted, the result data of the computation still may be used.

The nonvolatile memory cell array 20 includes memory cells located on crossing regions between a word line and a bit line. The memory cell may be, for example, one of a resistive random access memory (RRAM), a magnetic random access memory (MRAM), and a phase change random access memory (PRAM). The RRAM, MRAM, or PRAM is an example of a nonvolatile memory cell, and other nonvolatile memory cell also may be the memory cell of the nonvolatile memory cell array 20.

The reading unit 30 reads the result data output from the nonvolatile memory cell array 20. The nonvolatile memory cell array 20 outputs data stored in a memory cell selected by the address decoder 10 to the reading unit 30. The reading unit 30 reads the output data, which may be represented as, for example, ‘0’ or ‘1’. In the case when the address decoder 10 selects only a row address, the result data stored in a row address selected by the nonvolatile memory cell array 20 are simultaneously output to the reading unit 30. When a plurality of data is simultaneously output from the nonvolatile memory cell array 20, the reading unit 30 simultaneously reads the plural output data, and outputs the result of reading. Data output from the nonvolatile memory cell array 20 are result data of a specific computation.

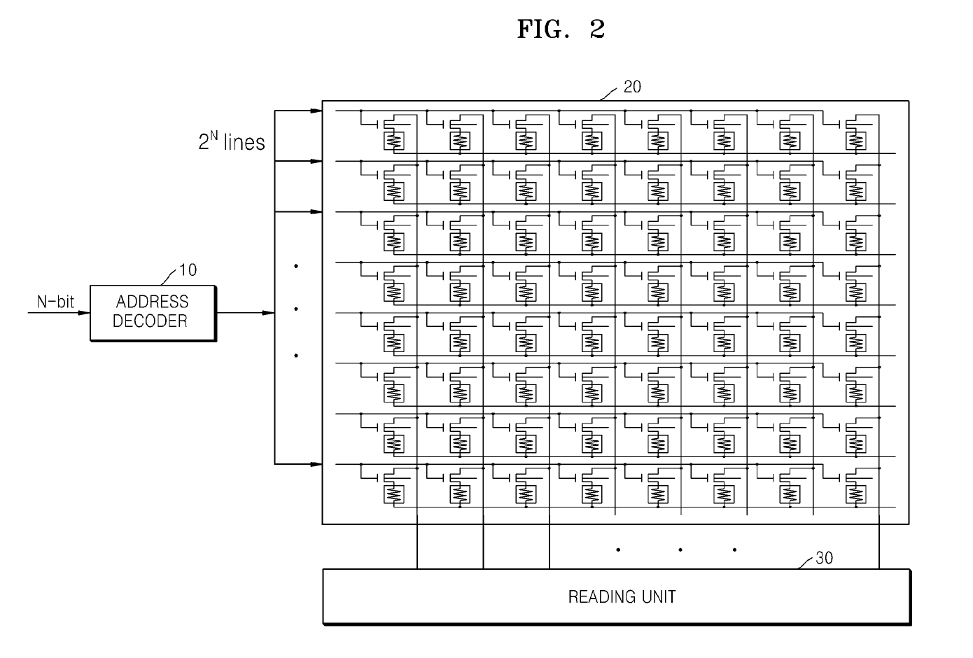

FIG. 2 is a drawing for explaining a nonvolatile memory apparatus 100 according to at least one example embodiment. The nonvolatile memory apparatus 100 includes a memory cell that does not lose stored data even if power is turned off. For example, the nonvolatile memory apparatus 100 may include a memory cell, for example, a PRAM that uses a phase change material, an RRAM that uses a variable resistance material such as complex metal oxides, and a ferroelectric random access memory (FRAM) that uses a ferroelectric capacitor. These memory apparatus fields have achieved performance improvements in integration density, operation speed, and secure of data reliability.

The nonvolatile memory cell array 20 includes a plurality of word lines, a plurality of bit lines, and a plurality of memory cells disposed in regions where the word lines and the bit lines cross each other.

The memory cells may be commonly connected to the same source line (not shown). Alternatively, the nonvolatile memory cell array 20 may be divided into at least two cell regions, and each of the cell regions may be connected to a different source line.

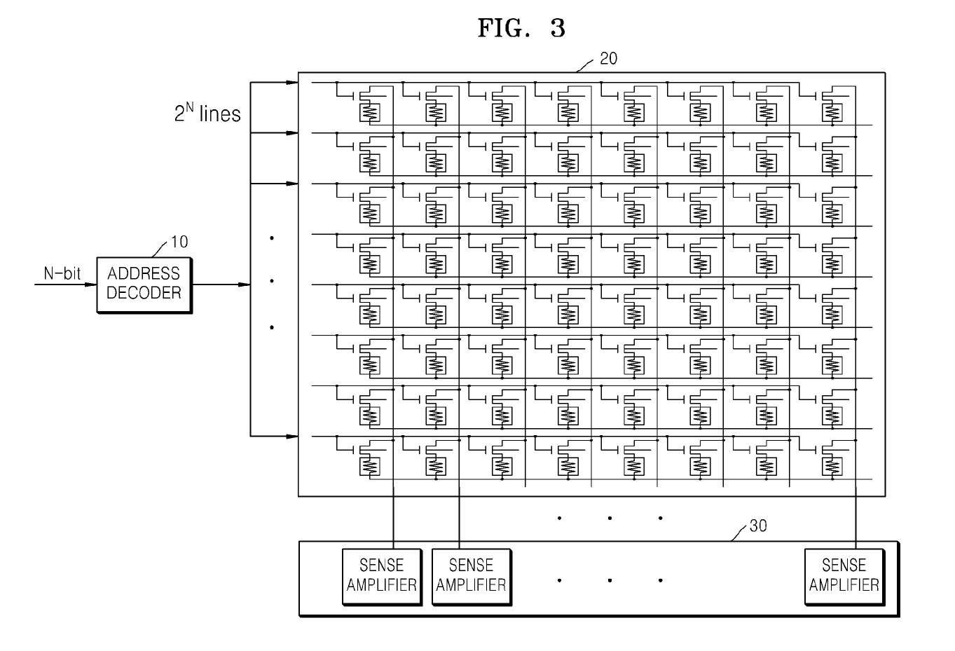

FIG. 3 is a drawing for explaining a nonvolatile memory apparatus 100 that includes sense amplifiers according to at least one example embodiment. According to at least one example embodiment, the reading unit 30 may include an number of sense amplifiers equal to the number of bit lines in the nonvolatile memory cell array 20. Each of the sense amplifiers of the reading unit 30 reads data output to the bit lines. Although a specific line of the nonvolatile memory cell array 20 is selected and data of the selected line are simultaneously output, the reading unit 30 may read the data of plural bit lines simultaneously since the reading unit 30 includes sense amplifiers respectively connected to each of the bit lines, respectively, through which data are output. When data are read, a data voltage of the memory cell is transferred to the sense amplifier through the bit line. The sense amplifier outputs a digital signal by sensing and amplifying a voltage difference between a reference voltage VREF and a data voltage. For example, if a signal inputted to the address decoder 10 is N-bit, the word lines and bit lines of the nonvolatile memory cell array 20 are respectively 2N and M, where N and M are both positive integers. That is, the nonvolatile memory cell array 20 data of M-bit are output to the reading unit 30. In this case, the reading unit 30 simultaneously reads M-bit data by using M number of sense amplifiers.

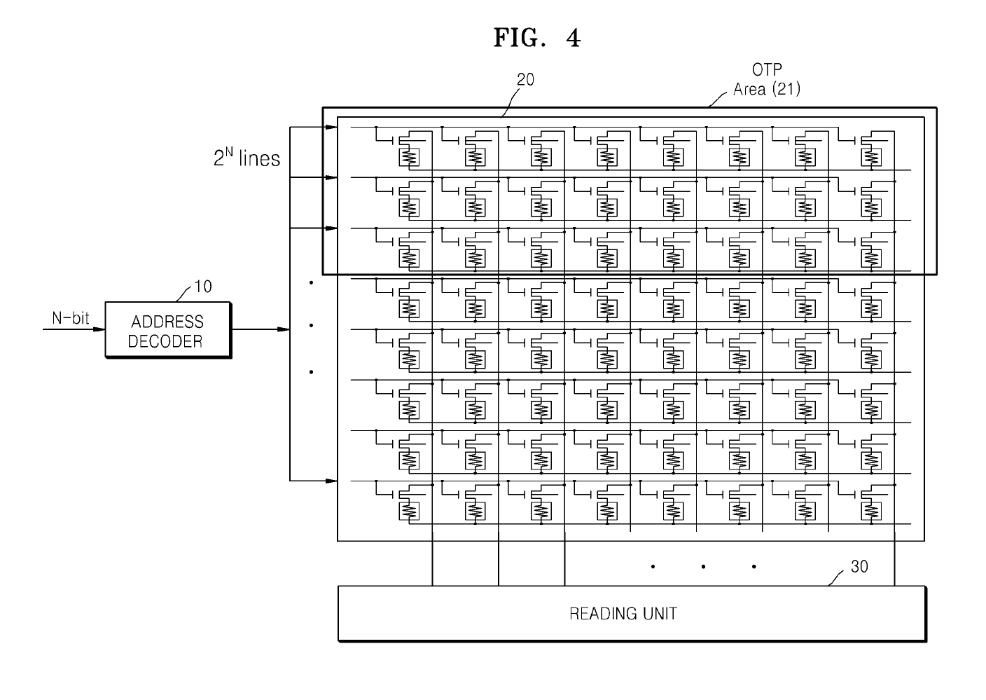

FIG. 4 is a drawing for explaining a nonvolatile memory apparatus that includes an OTP area according to at least one example embodiment. Some of the nonvolatile memory cells are designated as a one-time programmable (OTP) area 21, and result data of computations are stored in the OTP area 21. The OTP area 21 is a memory area in which one time writing is allowed. Since only one time writing is allowed in the OTP area 21, data written in the OTP area 21 are not updated. As depicted in FIG. 4, the OTP area 21 may be formed on a portion of the nonvolatile memory cell array 20.

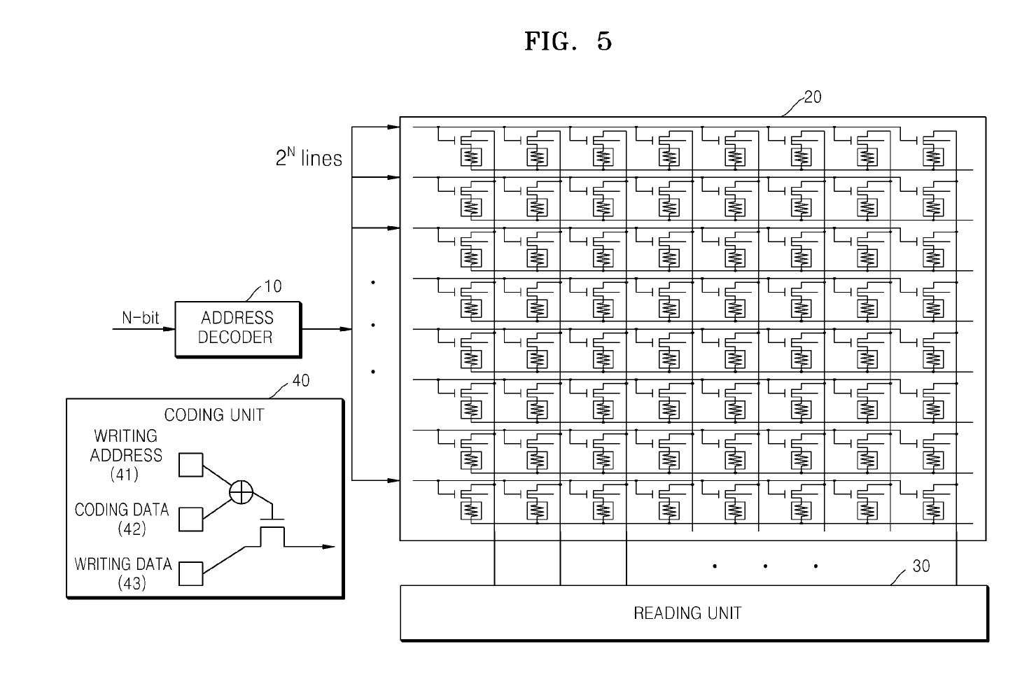

FIG. 5 is a drawing for explaining a nonvolatile memory apparatus 100 that performs a coding operation according to at least one example embodiment. The nonvolatile memory apparatus 100 performs a coding operation of data stored in the nonvolatile memory cell array 20 by using a coding unit 40. The coding unit 40 performs a coding operation on a writing address 41 by using a coding data 42. Writing data 43 corresponding to the writing address 41 is inputted to a bit line of the nonvolatile memory cell array 20 at an address corresponding to the coded address resulting from the coding operation performed on the writing address and coding data 42. For example, according to at least one example embodiment, the coding unit 40 may perform an XOR operation on the writing address 41 and the coding data 42 to generate the coded address. The coded address may then be provided by the coding unit 40 to the address decoder 10 and the writing data 43 may be stored in the nonvolatile memory cell array 20 at the coded address. In other words, in order to protect the writing data 43, when the writing data 43 is stored in the nonvolatile memory cell array 20, the coding unit 40 does not store the writing data 43 in an address corresponding to the writing address 41, but stores the writing data 43 in a coded address by using the coding data 42. Accordingly, without knowing the coding data 42, it is impossible to know the address in which the writing data 43 is stored.

Since the writing data 43 is stored in the nonvolatile memory cell array 20 by being coded, even if power of the nonvolatile memory apparatus 100 is turned off, the writing data 43 is not erased. Also, the writing data 43 may be able to be updated by a new data. When the writing data 43 is stored in the OTP area 21 in FIG. 4, the modification of the writing data 43 may be blocked.

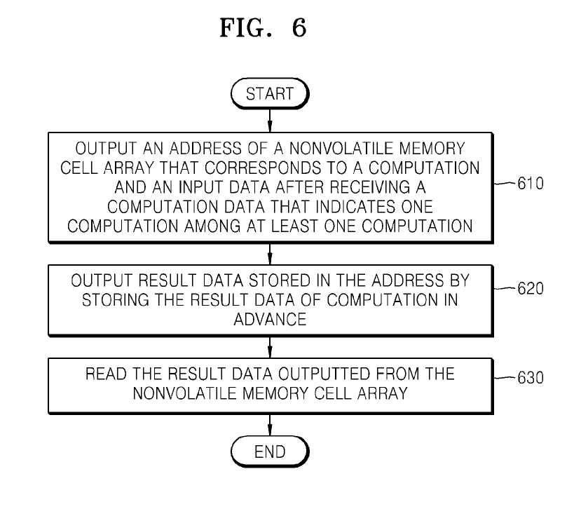

FIG. 6 is a flowchart for explaining a method of operating a nonvolatile memory apparatus 100 according to at least one example embodiment. The nonvolatile memory apparatus 100 receives a computation data that indicates one computation among a plurality of computations and an input data for computation, and outputs an address of the nonvolatile memory cell array 20 corresponding to the computation and input data. The nonvolatile memory apparatus 100 stores the result data of computations in advance and outputs the result data stored in an address. The nonvolatile memory apparatus 100 reads the result data output from the nonvolatile memory cell array 20.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A nonvolatile memory apparatus comprising:
a nonvolatile memory cell array including a plurality of memory cells;
an address decoder configured to receive computation data that indicates a computation from among a plurality of computations and an input data for computation, and the address decoder configured to output an address of the nonvolatile memory cell array corresponding to the indicated computation and input data,
the nonvolatile memory cell array being configured to output result data stored at the output address, the result data corresponding to a previous computation performed before receipt of the computation data; and
a reading unit configured to read the result data output from the nonvolatile memory cell array.

2. The nonvolatile memory apparatus of claim 1, wherein the reading unit comprises:
a number of sense amplifiers equal to a number of bit lines of the nonvolatile memory cell array.

3. The nonvolatile memory apparatus of claim 1, wherein the address decoder is a row decoder of the nonvolatile memory cell array.

4. The nonvolatile memory apparatus of claim 3, wherein the nonvolatile memory cell array is configured to simultaneously output a plurality of bits of the result data in a line selected by the row decoder.

5. The nonvolatile memory apparatus of claim 1, wherein the nonvolatile memory cells are each one of a resistive random access memory (RRAM), a magnetic random access memory (MRAM), and a phase change random access memory (PRAM).

6. The nonvolatile memory apparatus of claim 1, further comprising:
a coding unit configured to perform a coding operation on a writing address of writing data that is inputted to the bit lines of the nonvolatile memory cell array.

7. The nonvolatile memory apparatus of claim 6, wherein the coding unit is configured to perform a coding operation by using the writing address and a coding data.

8. The nonvolatile memory apparatus of claim 1, wherein at least some of the plurality of memory cells in the nonvolatile memory cell array are in a one-time programmable (OTP) area of the nonvolatile memory cell array, and the result data of computation is stored in the OTP area.

9. A method of operating a nonvolatile memory apparatus, the method comprising:
receiving a computation data that indicates one computation among a plurality of computations;
outputting an address of a nonvolatile memory cell array that corresponds to the indicated computation and an input data after receiving the computation data;
outputting result data stored at the output address, the result data corresponding to a previous computation performed before receipt of the computation data; and
reading the result data output from the nonvolatile memory cell array.

10. The method of claim 9, wherein the reading of the result data comprises:
reading the result data with a number of sense amplifiers equal to a number of bit lines of the nonvolatile memory cell array.

11. The method of claim 9, wherein the output address indicates a line of the nonvolatile memory cell array.

12. The method of claim 11, wherein the outputting of the result data comprises:
simultaneously outputting a plurality of bits of the result data stored in a line of the nonvolatile memory cell array indicated by the output address.

13. The method of claim 9, further comprising:
performing coding of a writing address of writing data that is inputted to the bit lines of the nonvolatile memory cell array.

14. The method of claim 13, wherein the performing of the coding comprises:
performing coding the writing data by using the writing address and a coding data.

15. The method of claim 9, further comprising:
storing the result data of computation in a one-time programmable (OTP) area, the OTP area including at least some of a plurality of cells included in the nonvolatile memory cell array.
